(19) United States
(12) Patent Application Publication
(10) Pub. No.: US 2019/0206946 A1
(43) Pub. Date: Jul. 4, 2019

(54) DISPLAY SUBSTRATE, DISPLAY DEVICE AND MANUFACTURING METHOD OF DISPLAY SUBSTRATE

(71) Applicant: BOE Technology Group Co., Ltd., Beijing (CN)

(72) Inventors: Zhengyin XU, Beijing (CN); Qingyun Bai, Beijing (CN)

(21) Appl. No.: 16/045,922

(22) Filed: Jul. 26, 2018

(30) Foreign Application Priority Data
Jan. 2, 2018 (CN) 201810002850.3

(51) Int. Cl. H01L 27/32; H01L 51/56

(52) U.S. Cl. CPC H01L 27/326; H01L 27/3246; H01L 2227/323; H01L 51/56; H01L 27/3276

(57) ABSTRACT

A display substrate, display device and manufacturing method of display substrate are provided. The display substrate includes: base substrate, and pixel defining pattern, heating circuit pattern, light-emitting layer and auxiliary light-emitting layer on one side of the base substrate. The pixel defining pattern has hollowed-out areas and bank disposed around hollowed-out areas where the light-emitting layer is located, and the auxiliary light-emitting layer at least partly covers the hollowed-out areas and area where the bank is located; the heating circuit pattern is on one side of the auxiliary light-emitting layer above the bank; and the auxiliary light-emitting layer includes first and second areas, orthographic projection of first area on the base substrate overlaps with orthographic projection of the hollowed-out areas on the base substrate, and orthographic projection of second area on the base substrate at least partly overlaps with orthographic projection of the heating circuit pattern on the base substrate.

This application claims priority to Chinese Patent Application No. 201810002850.3, filed with the State Intellectual Property Office on Jan. 2, 2018 and titled “DISPLAY SUBSTRATE, AND MANUFACTURING METHOD OF DISPLAY SUBSTRATE, AND DISPLAY DEVICE”, the entire contents of which are incorporated herein by reference.

### TECHNICAL FIELD

The present disclosure relates to a display substrate, a display device and a manufacturing method of a display substrate.

### BACKGROUND

As a current-type light-emitting device, an organic light emitting diode (OLED) is increasingly applied in the high-performance display field because of its features such as self light emission, quick response, wide viewing angles and the like.

In general, an existing OLED display substrate comprises: a base substrate, and a pixel defining layer and a self-luminous device disposed on one side of the base substrate. Since the existing OLED display substrate has a higher and higher pixel resolution and a smaller and smaller pixel pitch, inter-pixel current crosstalk may occur.

### SUMMARY

There are provided in the embodiments of the present disclosure a display substrate, a display device and a manufacturing method of a display substrate.

In an aspect, there is provided a display substrate, comprising:

a base substrate, and a pixel defining pattern, a heating circuit pattern, a light-emitting layer and an auxiliary light-emitting layer located on one side of the base substrate,

herein, the pixel defining pattern has a plurality of hollowed-out areas arranged in an array and comprises a bank disposed around each of the hollowed-out areas in which the light-emitting layer is located, and the auxiliary light-emitting layer at least partly covers the hollowed-out areas and an area where the bank is located;

the heating circuit pattern is located on one side of the auxiliary light-emitting layer above the bank; and

the auxiliary light-emitting layer comprises: a first area and a second area, an orthographic projection of the first area on the base substrate overlaps with an orthographic projection of the hollowed-out areas on the base substrate, an orthographic projection of the second area on the base substrate at least partly overlaps with an orthographic projection of the heating circuit pattern on the base substrate, and the second area is used to cut off a lateral transmission of a current in the auxiliary light-emitting layer.

Optionally, the heating circuit pattern is located between one side of the bank away from the base substrate and the auxiliary light-emitting layer.

Optionally, the auxiliary light-emitting layer completely covers the hollowed-out areas and the area where the bank is located.

Optionally, the heating circuit pattern comprises a plurality of enclosed sub-patterns arranged in a matrix, and the plurality of enclosed sub-patterns are arranged in one-to-one correspondence with a plurality of sub-pixels of the display substrate.

Optionally, the heating circuit pattern is made of silver, indium tin oxide, aluminum or molybdenum.

Optionally, the display substrate further comprises: a first electrode and a second electrode, and a polarity of the first electrode is opposite to a polarity of the second electrode; and the first electrode is located between the base substrate and the auxiliary light-emitting layer, and the second electrode is located on one side of the auxiliary light-emitting layer away from the base substrate.

Optionally, the display substrate further comprises a pixel-driving circuit located between the base substrate and the pixel defining pattern.

Optionally, the auxiliary light-emitting layer comprises: a first carrier injection layer, a first carrier transport layer, a second carrier transport layer and a second carrier injection layer being stacked along a direction away from the base substrate, and the light-emitting layer is located between the first carrier transport layer and the second carrier transport layer, and the first carrier and the second carrier are one of an electron and a hole, respectively.

Optionally, the second area is formed as the heating circuit pattern warms up and destroys a film layer structure located above the bank in the auxiliary light-emitting layer, after an external power supply provides a current to the heating circuit pattern.

In another aspect, there is provided a display device, comprising a display substrate, the display substrate comprising: a base substrate, and a pixel defining pattern, a heating circuit pattern, a light-emitting layer and an auxiliary light-emitting layer located on one side of the base substrate,

herein, the pixel defining pattern has a plurality of hollowed-out areas arranged in an array, and comprises a bank disposed around each of the hollowed-out areas in which the light-emitting layer is located, and the auxiliary light-emitting layer at least partly covers the hollowed-out areas and an area where the bank is located;

the heating circuit pattern is located on one side of the auxiliary light-emitting layer above the bank; and

the auxiliary light-emitting layer comprises: a first area and a second area, an orthographic projection of the first area on the base substrate overlaps with an orthographic projection of the hollowed-out areas on the base substrate, an orthographic projection of the second area on the base substrate at least partly overlaps with an orthographic projection of the heating circuit pattern on the base substrate, and the second area is used to cut off a lateral transmission of a current in the auxiliary light-emitting layer.

Optionally, the heating circuit pattern is located between one side of the bank away from the base substrate and the auxiliary light-emitting layer.

Optionally, the auxiliary light-emitting layer completely covers the hollowed-out areas and the area where the bank is located.

In still another aspect, there is provided a manufacturing method of a display substrate, comprising the steps of:

providing a base substrate;

forming on the base substrate a pixel defining pattern, a heating circuit pattern, a light-emitting layer and an auxiliary light-emitting layer, the pixel defining pattern having a plurality of hollowed-out areas arranged in an array, and comprising a bank disposed around each of the hollowed-out areas in which the light-emitting layer is located, and the auxiliary light-emitting layer at least partly covering the hollowed-out areas and an area where the bank is located, the heating circuit pattern being located on one side of the auxiliary light-emitting layer above the bank, and the heating circuit pattern being connected with an external power supply; and

providing, by the external power supply, a current to the heating circuit pattern, so that the heating circuit pattern warms up and destroys a film layer structure located above the bank in the auxiliary light-emitting layer.

Optionally, the step of forming on the base substrate a pixel defining pattern, a heating circuit pattern, a light-emitting layer and an auxiliary light-emitting layer, comprising the steps of:

forming the pixel defining pattern and the heating circuit pattern on the base substrate, the heating circuit pattern being located on one side of the bank away from the base substrate; and

forming the light-emitting layer and the auxiliary light-emitting layer on the base substrate formed with the heating circuit pattern and the pixel defining pattern.

Optionally, the step of providing, by the external power supply, a current to the heating circuit pattern, comprising the step of: providing, by the external power supply, a pulse current to the heating circuit pattern.

Optionally, the step of forming on the base substrate the pixel defining pattern and the heating circuit pattern, comprising the steps of: forming on the base substrate a pixel defining layer; forming the heating circuit pattern on one side of the pixel defining layer away from the base substrate; and adopting a patterning process for the pixel defining layer to form the pixel defining pattern.

Optionally, the step of forming the heating circuit pattern on one side of the pixel defining layer away from the base substrate, comprising the steps of: forming a heating circuit layer on the base substrate formed with the pixel defining layer; and adopting a patterning process for the heating circuit layer to form the heating circuit pattern.

Optionally, before the step of forming on the base substrate a pixel defining pattern, a heating circuit pattern, a light-emitting layer and an auxiliary light-emitting layer, the method further comprises the steps of: forming a first electrode on the base substrate; the step of forming on the base substrate a pixel defining pattern, a heating circuit pattern, a light-emitting layer and an auxiliary light-emitting layer, comprising the steps of: forming the pixel defining pattern on the base substrate formed with the first electrode; forming the heating circuit pattern on the base substrate formed with the pixel defining pattern by using a conductive material different from a material of the first electrode; and forming the light-emitting layer and the auxiliary light-emitting layer on the base substrate formed with the heating circuit pattern.

Optionally, the method further comprises the step of: forming a second electrode on the base substrate formed with the light-emitting layer and the auxiliary light-emitting layer, a polarity of the second electrode being opposite to a polarity of the first electrode.

Optionally, before the step of forming the first electrode on the base substrate, the method further comprises the step of: forming a pixel-driving circuit on the base substrate.

### BRIEF DESCRIPTION OF THE DRAWINGS

FIG. 1 is a schematic diagram of a structure of a display substrate already known to the inventors;

FIG. 2 is a schematic diagram of a structure of a display substrate according to an embodiment of the present disclosure;

FIG. 3 is a schematic diagram of a structure of another display substrate according to an embodiment of the present disclosure;

FIG. 4 is a schematic diagram of a structure of a heating circuit pattern and a pixel defining pattern according to an embodiment of the present disclosure;

FIG. 5 is a schematic diagram of a structure of still another display substrate according to an embodiment of the present disclosure;

FIG. 6 is a flow chart of a manufacturing method of a display substrate according to an embodiment of the present disclosure;

FIG. 7 is a flow chart of another manufacturing method of a display substrate according to an embodiment of the present disclosure; and

FIG. 8 is a process flow diagram illustrating forming a pixel defining pattern and a heating circuit pattern on a base substrate according to an embodiment of the present disclosure.

### DETAILED DESCRIPTION

In order to make the principle and advantages of the present disclosure clearer, the embodiments of the present disclosure are described in further details below in conjunction with the accompanying drawings.

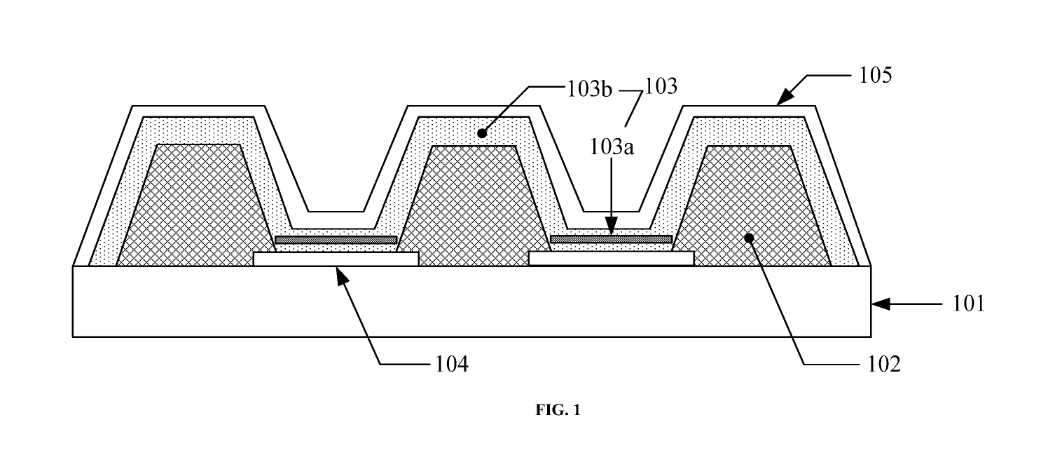

FIG. 1 is a schematic view illustrating an OLED display substrate known to the inventor. As shown in FIG. 1, the display substrate comprises: a base substrate 101, a pixel defining layer 102 and a self-luminous device 103. Herein, the self-luminous device 103 comprises: a light-emitting layer 103a, an auxiliary light-emitting layer 103b arranged in an entire layer, an anode 104 and a cathode 105. The auxiliary light-emitting layer 103b can comprise a hole injection layer, a hole transport layer, an electron transport layer and an electron injection layer, which are stacked in sequence (not shown). The light-emitting layer 103a is disposed between the hole transport layer and the electron transport layer.

At present, in order to improve a display effect of a display device, an OLED display substrate has a higher and higher pixel resolution and a smaller and smaller pixel pitch. In the display substrate as shown in FIG. 1, inter-pixel current crosstalk may occur. For example, it is assumed that pixels of the OLED display substrate comprise: red sub-pixels, green sub-pixels and blue sub-pixels. When electrical signals are loaded on the blue sub-pixels to illuminate the blue sub-pixels, a current generated in a blue sub-pixel area can be laterally transmitted from a hole transport layer or a hole injection layer to a sub-pixel area adjacent to the blue sub-pixels, due to a smaller pixel pitch, so that the red sub-pixels and the green sub-pixels adjacent to the blue sub-pixels are also illuminated.

In addition, power consumption requirements of a display substrate are currently becoming increasingly stringent. In order to reduce a power consumption of a display substrate, a p-doping type hole transport material is usually selected for preparation of a hole transport layer. Since the p-doping type hole transport material has a preferred electric conductivity, the inter-pixel current crosstalk problem grows worse. Therefore, the display substrate has a lower display color purity and the display device has a poorer display quality.

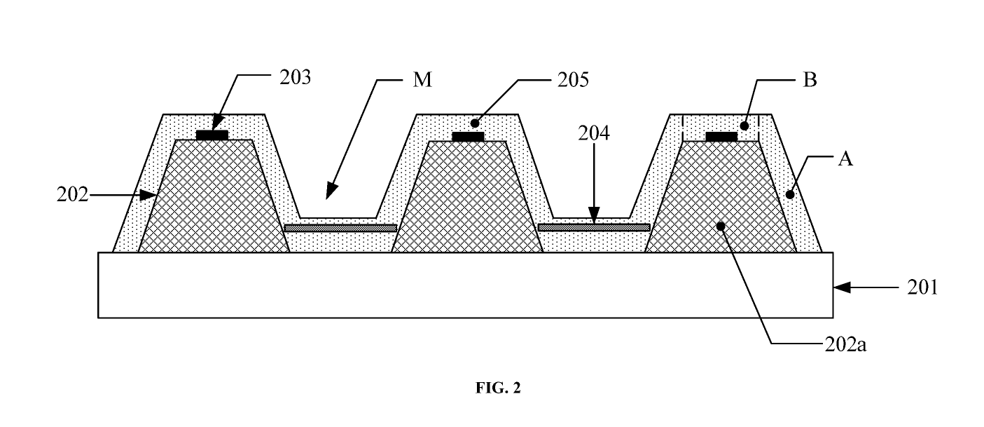

FIG. 2 is a schematic diagram of a structure of a display substrate according to an embodiment of the present disclosure. As shown in FIG. 2, the display substrate may include:

a base substrate 201, and a pixel defining pattern 202, a heating circuit pattern 203, a light-emitting layer 204 and an auxiliary light-emitting layer 205 located on one side of the base substrate 201.

Herein, the pixel defining pattern 202 has a plurality of hollowed-out areas M arranged in an array and comprises a bank 202a disposed around each of the hollowed-out areas M in which the light-emitting layer 204 is located. The auxiliary light-emitting layer 205 at least partly covers the hollowed-out areas M and an area where the bank 202a is located. Each of the hollowed-out areas M corresponds to a sub-pixel.

Optionally, referring to FIG. 2, the auxiliary light-emitting layer 205 completely covers the hollowed-out areas M and the area where the bank 202a is located. That is to say, the auxiliary light-emitting layer 205 is arranged in an entire layer. Alternatively, the display substrate can be divided into a plurality of display areas, then the auxiliary light-emitting layer is arranged in blocks, and the auxiliary light-emitting layer in each of the display areas covers the hollowed-out areas in the display areas and an area where the bank is located. The structure and position of the auxiliary light-emitting layer are not limited in the embodiments of the present disclosure.

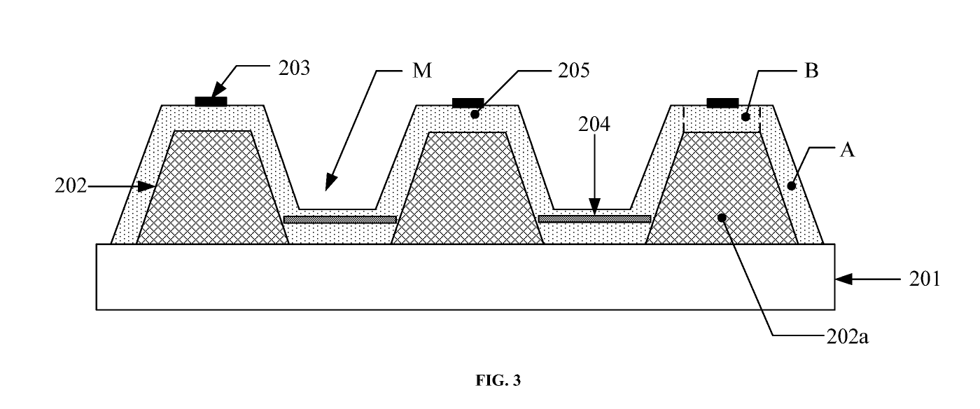

The heating circuit pattern 203 is located on one side of the auxiliary light-emitting layer 205 above the bank 202a. Alternatively, referring to FIG. 2, the heating circuit pattern 203 is located between one side of the bank 202a away from the base substrate 201 and the auxiliary light-emitting layer 205. Alternatively, referring to FIG. 3, the heating circuit pattern 203 is located on one side of the auxiliary light-emitting layer 205 above the bank 202a away from the base substrate 201, which will not be limited in the embodiments of the present disclosure.

Referring to FIG. 2 or FIG. 3, the auxiliary light-emitting layer 205 comprises: a first area A and a second area B. An orthographic projection of the first area A on the base substrate 201 overlaps with an orthographic projection of the hollowed-out areas M on the base substrate 201, and an orthographic projection of the second area B on the base substrate 201 at least partly overlaps with an orthographic projection of the heating circuit pattern 203 on the base substrate 201. The second area is used to cut off a lateral transmission of a current in the auxiliary light-emitting layer 205.

Optionally, the second area is formed as the heating circuit pattern warms up and destroys a film layer structure located above the bank in the auxiliary light-emitting layer, after an external power supply provides a current to the heating circuit pattern.

Optionally, the auxiliary light-emitting layer can comprise: a first carrier injection layer, a first carrier transport layer, a second carrier transport layer and a second carrier injection layer being stacked along a direction away from the base substrate in sequence. The light-emitting layer is located between the first carrier transport layer and the second carrier transport layer. The first carrier and the second carrier are one of an electron and a hole, respectively. That is to say, the first carrier is a hole and the second carrier is an electron. Alternatively, the first carrier is the electron and the second carrier is the hole. The structure formed of the light-emitting layer and the auxiliary light-emitting layer may also be referred to as a self-luminous device.

Exemplarily, the self-luminous device provided in the embodiments of the present disclosure may be an OLED display device, and may also be a Quantum Dot Light Emitting Diodes (QLED) display device.

In summary, with the display substrate provided in the embodiments of the present disclosure, a heating circuit pattern is provided on one side of the auxiliary light-emitting layer above the bank in the pixel defining pattern. When a self-luminous device is formed, a current is provided by the external power supply to the heating circuit pattern, to warm up the heating circuit pattern so as to destroy the film layer structure located above the bank in the auxiliary light-emitting layer to form the second area of the auxiliary light-emitting layer. Since the second area can cut off a lateral transmission of a current in the auxiliary light-emitting layer, even if a smaller pitch exists between the sub-pixels, the current generated in one sub-pixel area also cannot be transmitted to a neighboring sub-pixel area. This avoids interferences in color development in the neighboring sub-pixel areas, so as to improve the display color purity of the display substrate and further improve the display quality of the display device.

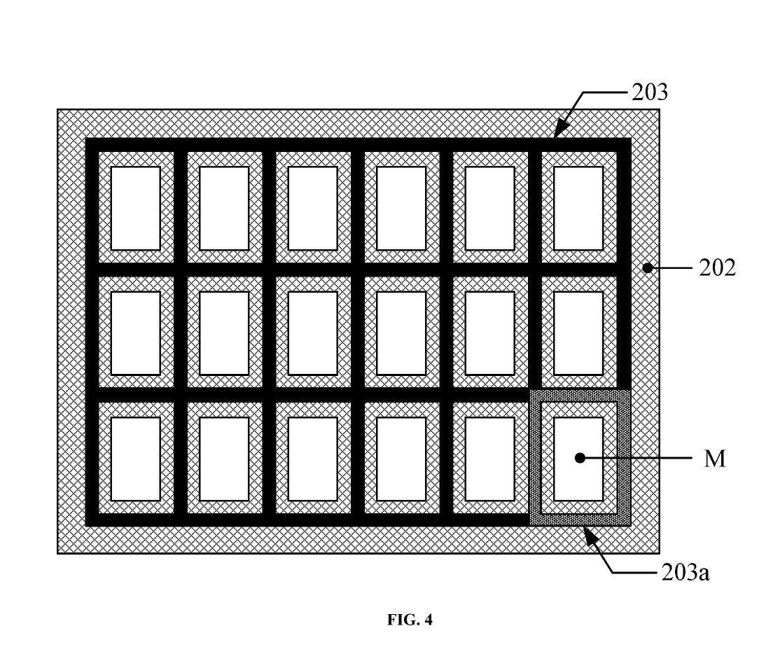

Optionally, as shown in FIG. 4, the heating circuit pattern 203 can comprise a plurality of enclosed sub-patterns 203a arranged in a matrix. The plurality of enclosed sub-patterns 203a is arranged in one-to-one correspondence with a plurality of sub-pixels of the display substrate. Since each of the hollowed-out areas M corresponds to one sub-pixel, the plurality of enclosed sub-patterns 203a is arranged in one-to-one correspondence with the hollowed-out areas M. The plurality of sub-pixels may comprise at least two colors of sub-pixels. For example, the plurality of sub-pixels may comprise: red sub-pixels, green sub-pixels and blue sub-pixels.

Optionally, the plurality of enclosed sub-patterns included in the heating circuit pattern may be all electrically connected. For example, as shown in FIG. 4, a shape of the heating circuit pattern 203 can be consistent with a shape of the pixel defining pattern 202. When the plurality of enclosed sub-patterns included in the heating circuit pattern are all electrically connected, the heating circuit pattern only needs to lead out a single conducting wire to be connected with an external power supply in the process of preparing a display substrate, and currents are provided by the external power supply simultaneously to the plurality of enclosed sub-patterns.

In the embodiments of the present disclosure, the enclosed sub-patterns only need to ensure that an enclosed area is formed in an outer periphery of each sub-pixel to form a second area on the auxiliary light-emitting layer between neighboring sub-pixels and prevent a current from laterally transmitting through the auxiliary light-emitting layer between the sub-pixels. An occurrence of a current crosstalk problem between any of two neighboring sub-pixels can be avoided to improve the display quality of the display substrate.

Optionally, when there is no electrical connection between the plurality of enclosed sub-patterns, each enclosed sub-pattern may lead out individually a conducting wire to be connected with an external power supply, in the process of preparing a display substrate. The connection relation between the plurality of enclosed sub-patterns is not limited in the embodiments of the present disclosure.

Optionally, the heating circuit pattern may be made of silver, indium tin oxide, aluminum or molybdenum, or other conductive materials. The materials of the heating circuit pattern are not limited in the embodiments of the present disclosure.

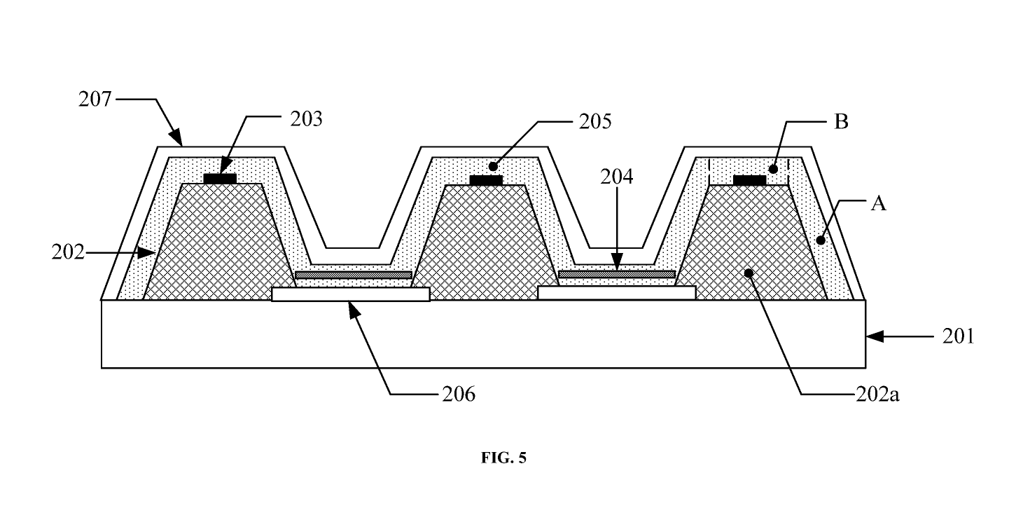

Optionally, as shown in FIG. 5, the display substrate further comprises: a first electrode 206 and a second electrode 207. A polarity of the first electrode is opposite to a polarity of the second electrode. For example, the first electrode is an anode and the second electrode is a cathode. Alternatively, the first electrode is the cathode and the second electrode is the anode. The first electrode 206 is located between the base substrate 201 and the auxiliary light-emitting layer 205. The second electrode 207 is located on one side of the auxiliary light-emitting layer 205 away from the base substrate 201.

Exemplarily, when the first electrode is the anode and the second electrode is the cathode, a film layer structure of the sub-pixel area (i.e., a light-emitting area of the display substrate) can comprise a hole injection layer, a hole transport layer, a light-emitting layer, an electron transport layer and an electron injection layer, which are stacked in sequence. When the first electrode is the cathode and the second electrode is the anode, the film layer structure of the sub-pixel area can comprise the electron injection layer, the electron transport layer, the light-emitting layer, the hole transport layer and the hole injection layer which are stacked in sequence.

Optionally, the display substrate further comprises a pixel-driving circuit disposed between the base substrate and the pixel defining pattern. For example, a thin film transistor (TFT) can be used in the pixel-driving circuit as a switching transistor and a driving transistor. The pixel-driving circuit provides electric signals to the sub-pixels in the display substrate.

In summary, a heating circuit pattern is provided on one side of the auxiliary light-emitting layer above the bank in the pixel defining pattern of the display substrate in the embodiments of the present disclosure. When a current is provided by the external power supply to the heating circuit pattern, warming up the heating circuit pattern can destroy the film layer structure located above the bank in the auxiliary light-emitting layer to form the second area of the auxiliary light-emitting layer. Since the second area can cut off a lateral transmission of a current in the auxiliary light-emitting layer, even if a smaller pitch exists between the sub-pixels, the current generated in one sub-pixel area also cannot be transmitted to a neighboring sub-pixel area. This avoids interferences in color development in the neighboring sub-pixel areas, so as to improve the display color purity of the display substrate and further improve the display quality of the display device.

The embodiments of the present disclosure provide a display device. The display device can comprise the display substrate as shown in FIG. 2, FIG. 3 or FIG. 5.

The display substrate comprises: a base substrate 201, and a pixel defining pattern 202, a heating circuit pattern 203, a light-emitting layer 204 and an auxiliary light-emitting layer 205 located on one side of the base substrate 201.

The pixel defining pattern 202 has a plurality of hollowed-out areas M arranged in an array. The pixel defining pattern 202 comprises a bank 202a disposed around each of the hollowed-out areas M in which the light-emitting layer 204 is located. The auxiliary light-emitting layer 205 at least partly covers the hollowed-out areas M and an area where the bank 202a is located. Each of the hollowed-out areas M corresponds to one sub-pixel.

Optionally, referring to FIG. 2, the auxiliary light-emitting layer 205 completely covers the hollowed-out areas M and the area where the bank 202a is located. That is to say, the auxiliary light-emitting layer 205 is arranged in an entire layer. Alternatively, the display substrate can be divided into a plurality of display areas, then the auxiliary light-emitting layer is arranged in blocks, and the auxiliary light-emitting layer in each of the display areas covers the hollowed-out areas in the display areas and an area where the bank is located. The structure and position of the auxiliary light-emitting layer are not limited in the embodiments of the present disclosure.

The heating circuit pattern 203 is located on one side of the auxiliary light-emitting layer 205 above the bank 202a. Optionally, referring to FIG. 2 or FIG. 5, the heating circuit pattern 203 is located between one side of the bank 202a away from the base substrate 201 and the auxiliary light-emitting layer 205. Alternatively, referring to FIG. 3, the heating circuit pattern 203 is located on one side of the auxiliary light-emitting layer 205 away from the base substrate 201, above the bank 202a, which will not be limited in the embodiments of the present disclosure.

Referring to FIG. 2 or FIG. 3, the auxiliary light-emitting layer 205 comprises: a first area A and a second area B. An orthographic projection of the first area A on the base substrate 201 overlaps with an orthographic projection of the hollowed-out areas M on the base substrate 201, and an orthographic projection of the second area B on the base substrate 201 at least partly overlaps with an orthographic projection of the heating circuit pattern 203 on the base substrate 201. The second area is used to cut off a lateral transmission of a current in the auxiliary light-emitting layer 205.

Optionally, the second area is formed by the heating circuit pattern warming up and destroying a film layer structure located above the bank in the auxiliary light-emitting layer, after an external power supply provides a current to the heating circuit pattern.

Optionally, the display device may be a mobile phone, a tablet, a TV, a display, a laptop computer, a digital photo frame, a navigator, or any other products or parts with display function.

In summary, according to the display device provided in the embodiments of the present disclosure, a heating circuit pattern is provided on one side of the auxiliary light-emitting layer above the bank in the pixel defining pattern. When a self-luminous device is formed, a current is provided by the external power supply to the heating circuit pattern, to warm up the heating circuit pattern so as to destroy the film layer structure located above the bank in the auxiliary light-emitting layer to form the second area of the auxiliary light-emitting layer. Since the second area can cut off a lateral transmission of a current in the auxiliary light-emitting layer, even if a smaller pitch exists between the sub-pixels, the current generated in one sub-pixel area also cannot be transmitted to a neighboring sub-pixel area. This avoids interferences in color development in the neighboring sub-pixel areas, so as to improve the display color purity of the display substrate and further improve the display quality of the display device.

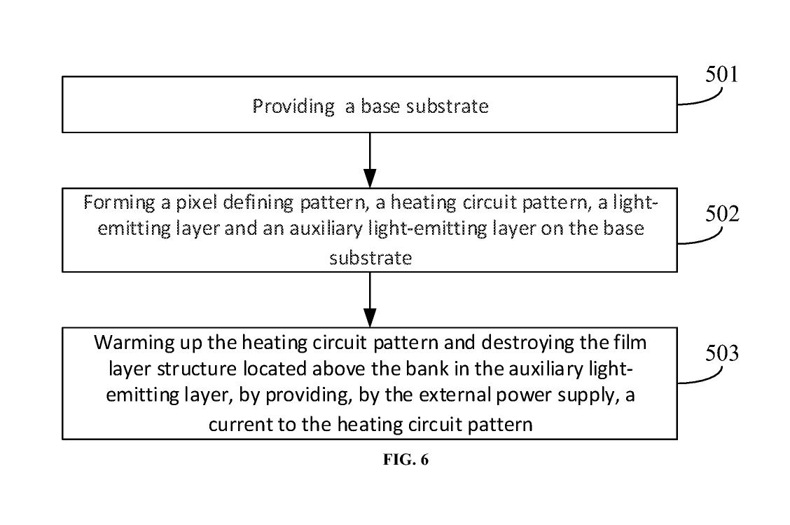

FIG. 6 is a flow chart of a manufacturing method of a display substrate according to an embodiment of the present disclosure. As shown in FIG. 6, the method may include the following steps.

In step 501, a base substrate is provided.

In step 502, a pixel defining pattern, a heating circuit pattern, a light-emitting layer and an auxiliary light-emitting layer are formed on the base substrate, the pixel defining pattern having a plurality of hollowed-out areas arranged in an array, and comprising a bank disposed around each of the hollowed-out areas in which the light-emitting layer is located, and the auxiliary light-emitting layer at least partly covering the hollowed-out areas and an area where the bank is located, the heating circuit pattern being located on one side of the auxiliary light-emitting layer above the bank, and the heating circuit pattern being connected with an external power supply.

The heating circuit pattern is disposed on one side of the auxiliary light-emitting layer above the pixel defining pattern, and the heating circuit pattern is connected with an external power supply.

Optionally, the pixel defining pattern and the heating circuit pattern can be formed on the base substrate, and the heating circuit pattern is located on one side of the bank away from the base substrate; the light-emitting layer and the auxiliary light-emitting layer are formed on the base substrate formed with the heating circuit pattern and the pixel defining pattern. The structure formed of the light-emitting layer and the auxiliary light-emitting layer can also be referred to as a self-luminous device.

In step 503, the heating circuit pattern is warmed up and the film layer structure located above the bank in the auxiliary light-emitting layer is destroyed, by providing, by the external power supply, a current to the heating circuit pattern.

Optionally, the auxiliary light-emitting layer can comprise: a first carrier injection layer, a first carrier transport layer, a second carrier transport layer and a second carrier injection layer being stacked along a direction away from the base substrate in sequence. The light-emitting layer is located between the first carrier transport layer and the second carrier transport layer. The first carrier and the second carrier are one of an electron and a hole, respectively. That is to say, the first carrier is a hole and the second carrier is an electron. Alternatively, the first carrier is the electron and the second carrier is the hole.

In the embodiments of the present disclosure, by providing, by the external power supply, a current to the heating circuit pattern, the current produces a thermal effect and thus can destroy the film layer structure located above the bank in the auxiliary light-emitting layer to form the second area. For example, the heat the heating circuit pattern generates enables an occurrence of thermal diffusion of molecules located inside the auxiliary light-emitting layer above the bank, so that materials of each film layer in the auxiliary light-emitting layer are mixed to obtain the second area. The second area is used to cut off a lateral transmission of a current in the auxiliary light-emitting layer.

Exemplarily, referring to FIG. 2 or FIG. 3 for the structure of the display substrate manufactured in the manufacturing method illustrated in FIG. 6, the explanations in the embodiments of the device side can be referred to for the description of each structure, and thus are not repeated in detail herein.

In summary, according to the manufacturing method of a display substrate provided in the embodiments of the present disclosure, a heating circuit pattern is provided on one side of the auxiliary light-emitting layer above the bank in the pixel defining pattern. When a self-luminous device is formed, a current is provided by the external power supply to the heating circuit pattern, to warm up the heating circuit pattern so as to destroy the film layer structure located above the bank in the auxiliary light-emitting layer, such that auxiliary light-emitting layer cannot perform lateral transmission current to neighboring sub-pixels even if a smaller pitch exists between the sub-pixels, the current generated in one sub-pixel area also cannot be transmitted to a neighboring sub-pixel area. This avoids interference in color development in the neighboring sub-pixel areas, so as to improve the display color purity of the display substrate and further improve the display quality of the display device.

In the embodiments of the present disclosure, the heating circuit pattern can be disposed between one side of the bank away from the base substrate and the auxiliary light-emitting layer. Alternatively, the heating circuit pattern can also be arranged on one side of the auxiliary light-emitting layer above the bank away from the base substrate. The following embodiments of the present disclosure take the heating circuit pattern disposed between one side of the bank away from the base substrate and the auxiliary light-emitting layer as an example, and demonstrate the manufacturing process of the display substrate.

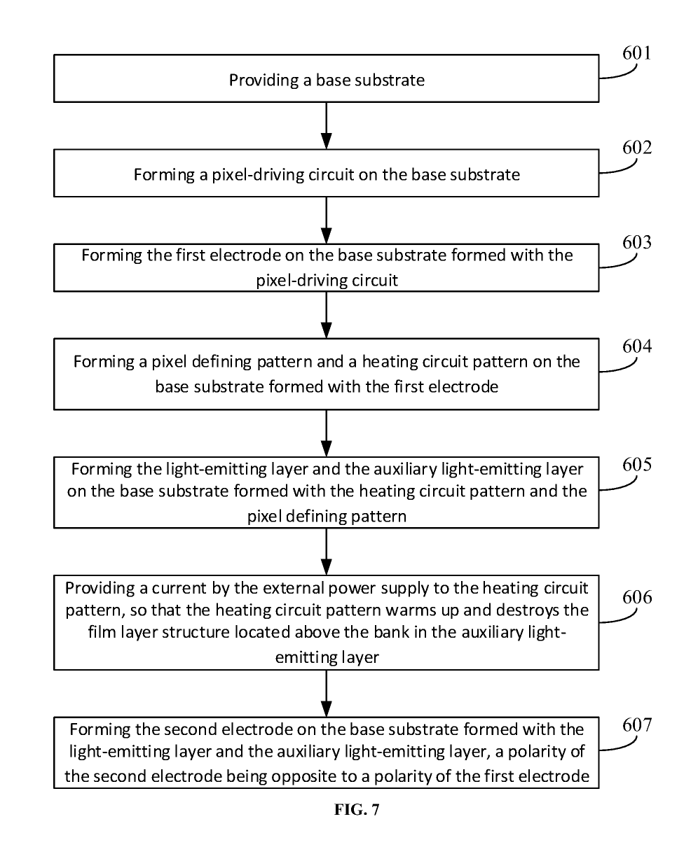

FIG. 7 is a flow chart illustrating a manufacturing method of another display substrate in the embodiments of the present disclosure. As shown in FIG. 7, this method comprises the following steps.

In step 601, a base substrate is provided.

Optionally, the base substrate can be a transparent substrate. Exemplarily, the base substrate can be a substrate made of light-conducting and nonmetallic materials with certain degree of hardness such as glass, quartz, transparent resins or the like.

In step 602, a pixel-driving circuit is formed on the base substrate.

Optionally, TFT can be used as a switching transistor and a driving transistor in the pixel-driving circuit. Exemplarily, techniques such as vacuum sputter or the like can be employed to form the TFT on the base substrate. The relevant techniques can be referred to for a process of forming the pixel-driving circuit, and thus are not repeated in detail herein.

In step 603, the first electrode is formed on the base substrate formed with the pixel-driving circuit.

Optionally, the first electrode can be made of silver, indium tin oxide, aluminum or molybdenum.

In step 604, a pixel defining pattern and a heating circuit pattern are formed on the base substrate formed with the first electrode.

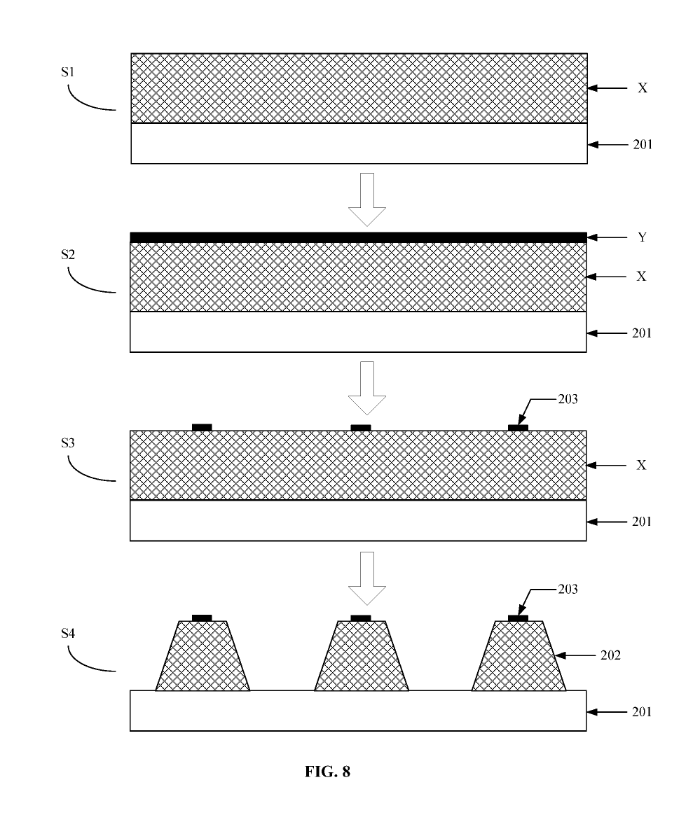

Optionally, FIG. 8 is a process flow chart of forming a pixel defining pattern and a heating circuit pattern on the base substrate in the embodiments of the present disclosure. As shown in FIG. 8, the technological process comprises the following steps.

In S1, a pixel defining layer X is formed on the base substrate 201.

Optionally, a coating process can be adopted to coat one layer of a photosensitive resin material having a certain thickness on a base substrate and thus a pixel defining layer is obtained.

For example, materials of the pixel defining layer can be polyimide (PI), polyethylene terephthalate (PET), polycarbonate (PC), polystyrene (PS), polyethylene (PE), polyamide (PA), or the like.

In S2, the heating circuit layer Y is formed on one side of the pixel defining layer X away from the base substrate 201.

Optionally, the heating circuit layer on one side of the pixel defining layer away from the base substrate can be formed in a manner of vacuum sputter or physical vapor deposition (PVD).

For example, the heating circuit layer can be made of silver, indium tin oxide, aluminum or molybdenum, or other conductive materials (indicative of the materials that can give off heat by way of energization), the materials of the heating circuit layer are not limited in the embodiments of the present disclosure.

In S3, the heating circuit pattern 203 is formed in a patterning process of the heating circuit layer Y.

The patterning process may comprise: a photoresist coating, an exposure, a development, an etching and a lifting off of a photoresist.

Optionally, as shown in FIG. 4, the heating circuit pattern 203 can comprise a plurality of enclosed sub-patterns 203a arranged in a matrix. The plurality of enclosed sub-patterns 203a are arranged in one-to-one correspondence with a plurality of sub-pixels of the display substrate. The plurality of sub-pixels may comprise at least two colors of sub-pixels. For example, the plurality of sub-pixels may comprise: red sub-pixels, green sub-pixels and blue sub-pixels.

Optionally, a plurality of enclosed sub-patterns included in the heating circuit pattern may be all electrically connected. For example, as shown in FIG. 4, a shape of the heating circuit pattern 203 can be consistent with a shape of the pixel defining pattern 202. When the plurality of enclosed sub-patterns included in the heating circuit pattern are all electrically connected, the heating circuit pattern only needs to lead out a single conducting wire be connected with an external power supply in the process of preparing a display substrate, and currents are provided by the external power supply simultaneously to the plurality of enclosed sub-patterns.

In S4, a patterning process is adopted for the pixel defining layer X to form a pixel defining pattern 202.

Optionally, the pixel defining layer can be exposed, developed and etched to form a pixel defining pattern.

In the technological procedures, a patterning process of the pixel defining layer is further employed and thus the pixel defining pattern is formed after the heating circuit pattern is formed. This can prevent damages to the first electrode due to over-etching in the process of forming the heating circuit pattern and ensure the reliability of the display substrate.

Optionally, when the first electrode differs from the heating circuit pattern in terms of materials, and the chosen etching solution can etch the material of the heating circuit pattern, but cannot etch the material of the first electrode, the pixel defining pattern can be initially formed and then the heating circuit pattern can be formed.

The embodiments of the present disclosure provide another method of forming a pixel defining pattern and a heating circuit pattern on a base substrate, comprising the following step.

The pixel defining pattern is formed on the base substrate formed with the first electrode, and the heating circuit pattern is formed on the base substrate formed with the pixel defining pattern by using a conductive material different from a material of the first electrode.

Optionally, the steps can be referred to for a process of forming the pixel defining pattern and a process of forming the heating circuit pattern, and thus are not repeated in detail herein.

In the embodiments of the present disclosure, the heating circuit pattern can also be formed in a silk-screen printing process on the pixel defining pattern, and the formation of the heating circuit pattern is not limited herein.

In step 605, the light-emitting layer and the auxiliary light-emitting layer are formed on the base substrate formed with the heating circuit pattern and the pixel defining pattern.

Optionally the first carrier injection layer, the first carrier transport layer, the light-emitting layer, the second carrier transport layer and the second carrier injection layer can be sequentially formed in an evaporation process. The first carrier injection layer, the first carrier transport layer, the second carrier transport layer and the second carrier injection layer can be arranged in an entire layer.

Exemplarily, when the first electrode is an anode, the hole injection layer, the hole transport layer, the light-emitting layer, the electron transport layer and the electron injection layer can be sequentially formed in an evaporation process.

In step 606, a current is provided by the external power supply to the heating circuit pattern, so that the heating circuit pattern warms up and destroys the film layer structure located above the bank in the auxiliary light-emitting layer.

Optionally, a pulse current can be provided by the external power supply to the heating circuit pattern. Since an intensity of the pulse current is periodically varied over time, intermittently providing a current to the heating circuit pattern can be implemented. This avoids damages to other film layers (such as the pixel defining pattern or the like) in the display substrate caused by overheating of the heating circuit pattern, and ensures the reliability of the display substrate. Destroying the film layer structure located above the bank in the auxiliary light-emitting layer can comprise: mixing the stacked structure in the auxiliary light-emitting layer, or damaging the film layer structure in the auxiliary light-emitting layer. Destroying the film layer structure located above the bank in the auxiliary light-emitting layer can prevent the hole transport layer or the hole injection layer from laterally transmitting inter-pixel current.

Optionally, after the film layer structure located above the bank in the auxiliary light-emitting layer is damaged, a connection of the heating circuit pattern with the external power supply can be disconnected.

In step 607, the second electrode is formed on the base substrate formed with the light-emitting layer and the auxiliary light-emitting layer, a polarity of the second electrode being opposite to a polarity of the first electrode.

Optionally, the second electrode can be formed in an evaporation process. In the process of forming the second electrode, a surface temperature of the self-luminous device should be lower than a maximum tolerable temperature of the self-luminous device, so as to avoid damaging the self-luminous device.

It should be noted that when the first electrode is an anode, the second electrode is a cathode; and when the first electrode is the cathode, the second electrode is the anode. The first electrode can comprise a plurality of sub-electrodes arranged at an array interval, and the second electrode can be exhibited in an integrated structure. Alternatively, the first electrode can be exhibited in the integrated structure, and the second electrode comprises a plurality of sub-electrodes arranged at the array interval. Alternatively, the first electrode and the second electrode can both comprise a plurality of sub-electrodes arranged at the array interval. It will not be limited in the embodiments of the present disclosure.

Referring to FIG. 5 for the structure of the display substrate manufactured in the manufacturing method as illustrated in FIG. 7, the explanations in the embodiments of the device side can be referred to for the description of each structure, and thus are not repeated in detail herein.

Optionally, after the step 607, the display substrate is subjected to subsequent techniques such as packaging, cutting or the like.

The sequencing of the manufacturing method steps for the display substrate in the embodiments of the present disclosure can be adjusted approximately. For example, the step 607 may be executed before the step 606. That is, the second electrode is initially formed and then a current is provided to the heating circuit pattern. The steps can also accordingly be added or reduced according to the circumstances. In the technical scope disclosed in the present disclosure, it is easily conceivable for persons skilled in the art that varied methods should fall within the protection scope of the present disclosure, and thus are not repeated in detail herein.

In summary, according to the manufacturing method of a display substrate provided in the embodiments of the present disclosure, a heating circuit pattern is provided on one side of the auxiliary light-emitting layer above the bank in the pixel defining pattern. When a self-luminous device is formed, a current is provided by the external power supply to the heating circuit pattern, to warm up the heating circuit pattern so as to destroy the film layer structure located above the bank in the auxiliary light-emitting layer, such that auxiliary light-emitting layer cannot transmit transverse current between the sub-pixels. Even if a smaller pitch exists between the sub-pixels, the current generated in one sub-pixel area also cannot be transmitted to a neighboring sub-pixel area. This avoids interference in color development in the neighboring sub-pixel areas, so as to improve the display color purity of the display substrate and further improve the display quality of the display device.

The foregoing are only optional embodiments of the present disclosure, and are not intended to limit the present disclosure. Within the spirit and principles of the disclosure, any modifications, equivalent substitutions, improvements, etc., are within the scope of protection of the present disclosure.

What is claimed is:

1. A display substrate, comprising:
a base substrate, and a pixel defining pattern, a heating circuit pattern, a light-emitting layer and an auxiliary light-emitting layer located on one side of the base substrate, wherein
the pixel defining pattern has a plurality of hollowed-out areas arranged in an array, and comprises a bank disposed around each of the hollowed-out areas in which the light-emitting layer is located, and the auxiliary light-emitting layer at least partly covers the hollowed-out areas and an area where the bank is located;
the heating circuit pattern is located on one side of the auxiliary light-emitting layer above the bank; and
the auxiliary light-emitting layer comprises: a first area and a second area, an orthographic projection of the first area on the base substrate overlaps with an orthographic projection of the hollowed-out areas on the base substrate, an orthographic projection of the second area on the base substrate at least partly overlaps with an orthographic projection of the heating circuit pattern on the base substrate, and the second area is used to cut off a lateral transmission of a current in the auxiliary light-emitting layer.

2. The display substrate according to claim 1, wherein the heating circuit pattern is located between one side of the bank away from the base substrate and the auxiliary light-emitting layer.

3. The display substrate according to claim 1, wherein the auxiliary light-emitting layer completely covers the hollowed-out areas and the area where the bank is located.

4. The display substrate according to claim 1, wherein the heating circuit pattern comprises a plurality of enclosed sub-patterns arranged in a matrix, and the plurality of enclosed sub-patterns are arranged in one-to-one correspondence with a plurality of sub-pixels of the display substrate.

5. The display substrate according to claim 1, wherein the heating circuit pattern is made of silver, indium tin oxide, aluminum or molybdenum.

6. The display substrate according to claim 1, wherein the display substrate further comprises: a first electrode and a second electrode, and a polarity of the first electrode is opposite to a polarity of the second electrode; and
the first electrode is located between the base substrate and the auxiliary light-emitting layer, and the second electrode is located on one side of the auxiliary light-emitting layer away from the base substrate.

7. The display substrate according to claim 1, wherein the display substrate further comprises a pixel-driving circuit located between the base substrate and the pixel defining pattern.

8. The display substrate according to claim 1, wherein the auxiliary light-emitting layer comprises: a first carrier injection layer, a first carrier transport layer, a second carrier transport layer and a second carrier injection layer being stacked along a direction away from the base substrate, and the light-emitting layer is located between the first carrier transport layer and the second carrier transport layer; and
the first carrier and the second carrier are one of an electron and a hole, respectively.

9. The display substrate according to claim 1, wherein the second area is formed by the heating circuit pattern warming up and destroying a film layer structure located above the bank in the auxiliary light-emitting layer after an external power supply provides a current to the heating circuit pattern.

10. A display device, comprising:
a display substrate, comprising:
a base substrate, and a pixel defining pattern, a heating circuit pattern, a light-emitting layer and an auxiliary light-emitting layer located on one side of the base substrate, wherein
the pixel defining pattern has a plurality of hollowed-out areas arranged in an array, and comprises a bank disposed around each of the hollowed-out areas in which the light-emitting layer is located, and the auxiliary light-emitting layer at least partly covers the hollowed-out areas and an area where the bank is located;
the heating circuit pattern is located on one side of the auxiliary light-emitting layer above the bank; and
the auxiliary light-emitting layer comprises: a first area and a second area, an orthographic projection of the first area on the base substrate overlaps with an orthographic projection of the hollowed-out areas on the base substrate, an orthographic projection of the second area on the base substrate at least partly overlaps with an orthographic projection of the heating circuit pattern on the base substrate, and the second area is used to cut off a lateral transmission of a current in the auxiliary light-emitting layer.

11. The display device according to claim 10, wherein the heating circuit pattern is located between one side of the bank away from the base substrate and the auxiliary light-emitting layer.

12. The display device according to claim 10, wherein the auxiliary light-emitting layer completely covers the hollowed-out areas and the area where the bank is located.

13. A manufacturing method of a display substrate, comprising the steps of:
providing a base substrate;
forming on the base substrate a pixel defining pattern, a heating circuit pattern, a light-emitting layer and an auxiliary light-emitting layer, the pixel defining pattern having a plurality of hollowed-out areas arranged in an array, and comprising a bank disposed around each of the hollowed-out areas in which the light-emitting layer is located, and the auxiliary light-emitting layer at least partly covering the hollowed-out areas and an area where the bank is located, the heating circuit pattern being located on one side of the auxiliary light-emitting layer above the bank, and the heating circuit pattern being connected with an external power supply; and
providing, by the external power supply, a current to the heating circuit pattern, so that the heating circuit pattern warms up and destroys a film layer structure located above the bank in the auxiliary light-emitting layer.

14. The method according to claim 13, wherein the step of forming on the base substrate a pixel defining pattern, a heating circuit pattern, a light-emitting layer and an auxiliary light-emitting layer, comprising the steps of:
forming the pixel defining pattern and the heating circuit pattern on the base substrate, the heating circuit pattern being located on one side of the bank away from the base substrate; and
forming the light-emitting layer and the auxiliary light-emitting layer on the base substrate formed with the heating circuit pattern and the pixel defining pattern.

15. The method according to claim 13, wherein the step of providing, by the external power supply, a current to the heating circuit pattern, comprising the step of: providing, by the external power supply, a pulse current to the heating circuit pattern.

16. The method according to claim 14, wherein the step of forming on the base substrate the pixel defining pattern and the heating circuit pattern, comprising the steps of:
forming on the base substrate a pixel defining layer;
forming the heating circuit pattern on one side of the pixel defining layer away from the base substrate; and
adopting a patterning process for the pixel defining layer to form the pixel defining pattern.

17. The method according to claim 16, wherein the step of forming the heating circuit pattern on one side of the pixel defining layer away from the base substrate, comprising the steps of:
forming a heating circuit layer on the base substrate formed with the pixel defining layer; and
adopting a patterning process for the heating circuit layer to form the heating circuit pattern.

18. The method according to claim 13, wherein before the step of forming on the base substrate a pixel defining pattern, a heating circuit pattern, a light-emitting layer and an auxiliary light-emitting layer, the method further comprises the steps of:
forming a first electrode on the base substrate;
the step of forming on the base substrate a pixel defining pattern, a heating circuit pattern, a light-emitting layer and an auxiliary light-emitting layer, comprising the steps of:
forming the pixel defining pattern on the base substrate formed with the first electrode;
forming the heating circuit pattern on the base substrate formed with the pixel defining pattern by using a conductive material different from a material of the first electrode; and
forming the light-emitting layer and the auxiliary light-emitting layer on the base substrate formed with the heating circuit pattern.

19. The method according to claim 18, wherein the method further comprises the step of: forming a second electrode on the base substrate formed with the light-emitting layer and the auxiliary light-emitting layer, a polarity of the second electrode being opposite to a polarity of the first electrode.

20. The method according to claim 18, wherein before the step of forming the first electrode on the base substrate, the method further comprises the step of: forming a pixel-driving circuit on the base substrate.
